(19) United States
(12) Patent Application Publication
(10) Pub. No.: US 2012/0194970 A1
(43) Pub. Date: Aug. 2, 2012

(54) DEVICE FOR ILLUMINATING MEANS

(75) Inventors: Conrad Wilhelmus Adriaan Verjans, Drachten (NL); Kristin Knappstein, Aachen (DE); Helmut Willnat, Kierspe (DE); Oris Papini, Kierspe (DE)

(73) Assignee: KONINKLIJKE PHILIPS ELECTRONICS N.V., EINDHOVEN (NL)

(21) Appl. No.: 12/519,174

(22) PCT Filed: Dec. 13, 2007
(86) PCT No.: PCT/EP07/10918

§ 371 Date: Apr. 18, 2012

(30) Foreign Application Priority Data
Dec. 19, 2006 (DE) 20 2006 019 239.5

(51) Int. Cl. H05K 7/00

(52) U.S. Cl. 361/679.01

(57) ABSTRACT

A device (70) for illumination means for contacting electrical appliances, in particular illumination means (50) with a frame (40) capable of enclosing the illumination means (50) at least locally at the outer edges thereof, and with at least two connection locations (60) capable of serving as electrical contact points (60) for the illumination means (50). These connection locations (60) comprise an electrically conductive material for providing the electrical contacting. The frame (40) is mounted around the illumination means (50), and the illumination means (50) together with the frame (40) are secured to a corresponding holder (FIG. 2).

The invention relates to a device for illumination means, in particular a holder for contacting electrical end appliances, in particular planar illumination means such as, for example, organic LEDs. Known holders comprise a frame that encloses the end appliance at the outer regions thereof at least locally and protects it mechanically against external influences. Such holders are widely used. Difficulties arise in some embodiments, however, in that the electrical contacts of the end appliance are usually unfavorably located in relation to an electrical supply contact point and accordingly can only be contacted with great difficulty. In addition, such holders are usually fastened to a support by means of a mechanical clamping or by other mechanical means, which renders it difficult to disconnect the relevant end appliance again. If these end appliances are designed for use, for example, as decorative units that are to be frequently exchanged, the operational life of such a holder will be correspondingly short.

It is accordingly an object of the invention to construct a holder of the kind mentioned in the opening paragraph such that the connection contacts are held in the frame in a simple manner so as to be readily accessible, and such that the holder has a retaining facility that renders it possible to mount and dismount the end appliance frequently in a simple manner.

This object is achieved by means of the characterizing features of claim 1. This device comprises a frame, in which frame at least two connection locations are provided which each comprise an electrically conductive contact face and by means of which a contacting to the end appliance is achieved. A simple electrical contact is provided in this manner which offers various contacting possibilities for current passage such as, for example, through a mating surface or through springs. Since the electrically conductive contact face comprises no mechanically loaded components, no problems will arise as regards the operational life of the contact faces even in the case of frequent contacting operations.

Advantageously, additional recesses or projections are provided at that side of the frame in which the contact faces are provided so as to facilitate an exact positioning of an end appliance that is arranged in a corresponding frame. Said corresponding frame should then have mating elevations or recesses by means of which a defined position can be achieved. This at the same time offers protection against an inadvertent electrically reversed connection.

The connection of the frame to the end appliance is achieved by magnetic forces that act either on the contact locations themselves or on additional fastening points recessed into the frame. As a result, the connection locations may serve both as electrical contacts and as fastening points for the end appliance. Alternatively, however, they may act as simple electrical contacts with separate fastening points being added.

In a special embodiment of the invention, the connection locations are manufactured from a magnetic material, so that the frame together with the end appliance can be fastened to any magnetizable material, as desired. Here, again, the connection location at the same time serves to contact the end appliance electrically. The connection location may consist of a permanent magnet or of an electromagnet, the latter obtaining its electrical energy either from a suitable holder or from a power source integrated in the frame.

In a special embodiment, the frame may cover not only the outer edges of the end appliance, but also several portions of the end appliance, for example for achieving decorative effects on the illumination means. There are substantially no limits imposed on the shape of the frame in such a case.

An embodiment of the invention is shown in the drawings, in which:

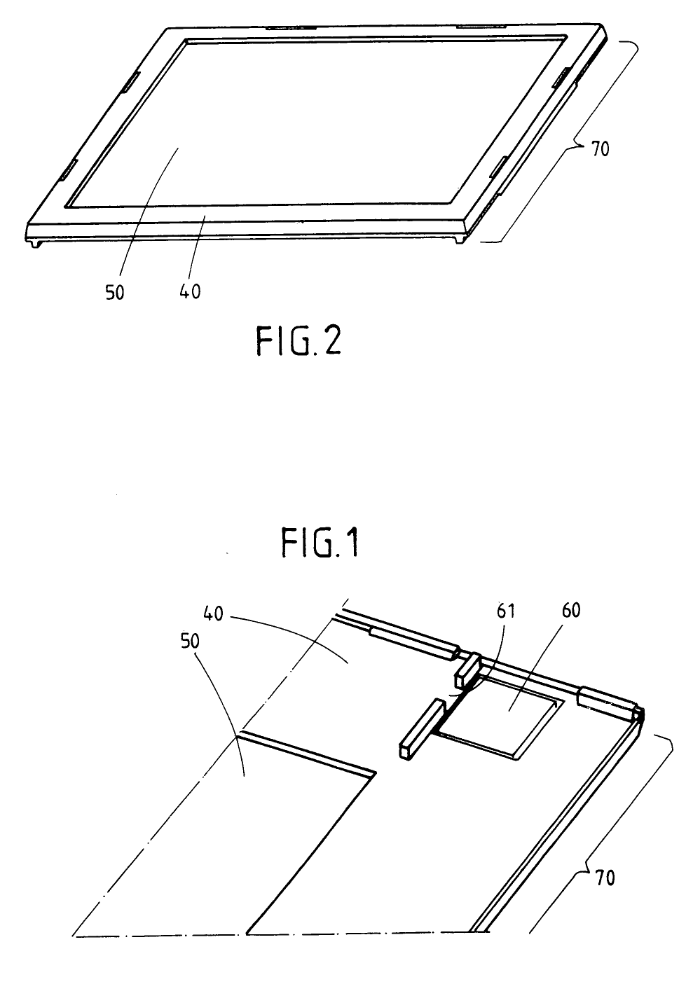

FIG. 1 shows a device according to the invention in frontal perspective view, and

FIG. 2 shows part of the rear of the frame.

The device 70 shown in the drawings comprises an electrical end appliance, i.e. an illumination means 50, and a frame 40 for retaining this illumination means 50. The frame 40 holds the illumination means 50 by its outer edges, circumferentially in the present case.

Connection locations 60 providing an electrical contacting with the illumination means 50 lie recessed in the frame 40, i.e. at the rear of this frame 50, which is made from synthetic resin. These connection locations 60 take the form of magnetic or magnetizable surfaces. Positioning elements 61 consisting of elevations on the frame 40 are arranged around the connection locations 60. In FIG. 1, these positioning elements 61 consist mainly of synthetic resin studs between which open spaces are left. A suitable holder should have mating counter-pieces for contacting, so that the frame 40 including the illumination means 50 can be inserted in a defined position.

The positioning elements 61 are not limited to the vicinity of the connection surfaces 60: they may be distributed over the entire surface area of the frame 40. Similarly, recesses and elevations may be provided in and on the frame 40 for facilitating an insertion of the illumination means into a corresponding holder.

The device according to the invention as shown in the drawings merely serves as an example. The invention is by no means limited thereto. Various modifications are indeed possible; for example, the material of the frame may be a material other than a synthetic resin, for example aluminum. The end user is presented with a wide variety of design possibilities thereby.

### LIST OF REFERENCE NUMERALS

40 frame

50 illumination means

60 connection location

61 positioning means

70 device

1. A device for illumination means, comprising a frame capable of enclosing an illumination means at least locally at the outer edges thereof, wherein
the frame has at least two connection locations serving as electrical contact locations for an illumination means,
said connection locations comprise an electrically conductive material, and
one or more fastening points are provided for fastening the device to a holder by means of magnetism.

2. A device as claimed in claim 1, characterized in that the connection locations further serve as the fastening points.

3. A device as claimed in claim 1, wherein the connection locations are provided as recesses in the frame.

4. A device as claimed in claim 1, wherein the connection locations are provided as elevations on the frame.

5. A device as claimed in claim 1, wherein the connection locations are provided flush with the surface of the frame.

6. A device as claimed in claim 1, wherein the connection locations are provided in a common edge at the sides of the frame.

7. A device as claimed in claim 1, wherein the connection locations are provided at different sides of the frame.

8. A device as claimed in claim 1, wherein positioning means are provided which render it possible to fasten the device in a defined position to the holder.

9. A device as claimed in claim 1, wherein the positioning means comprise projections on the frame.

10. A device as claimed in claim 1, wherein the positioning means comprise recesses in the frame.

11. A device as claimed in claim 1, wherein the connection locations are made from a magnetizable material.

12. A device as claimed in claim 1, wherein the connection locations are made from a magnetized material.

13. A device as claimed in claim 12, wherein a magnetic field in a contact face of a connection location is generated by a permanent magnet.

14. A device as claimed in claim 12, wherein a magnetic field in a contact face of a connection location is generated by an electromagnet.

15. A device as claimed in claim 14, wherein the energy for the electromagnet is stored at least temporarily.

16. A device as claimed in claim 3, wherein an additional fastening point is made from a magnetizable material.

17. A device as claimed in claim 3, wherein an additional fastening point is made from a magnetized material.

18. A device as claimed in claim 1, wherein the connection location is mounted under spring pressure in the frame.
